(19) United States
(12) Patent Application Publication
(10) Pub. No.: US 2018/0062729 A1
(43) Pub. Date: Mar. 1, 2018

(54) ELECTRONIC EQUIPMENT CABINETS HAVING RADIO FREQUENCY RELAYS

(71) Applicant: CommScope Technologies LLC, Hickory, NC (US)

(72) Inventors: Kevin E. Linehan, Rowland, TX (US); Michael Guerin, St. Charles, IL (US)

(21) Appl. No.: 15/680,289

(22) Filed: Aug. 18, 2017

Related U.S. Application Data
(60) Provisional application No. 62/378,783, filed on Aug. 24, 2016.

(51) Int. Cl. H04B 7/14; H05K 5/04; H05K 7/18

(52) U.S. Cl. CPC H04B 7/14; H04W 72/0406; H05K 7/186; H05K 5/04

(57) ABSTRACT

Electronic equipment cabinets include a relay that has an internal antenna, an external antenna and a transmission path therebetween. The internal antenna is located at least partially within the cabinet and the external antenna is located at least partially exterior to a wall of the cabinet. The relay is configured to receive uplink wireless transmissions from the wireless Internet-of-Things transceivers included on electronic devices mounted within the cabinet and to forward and rebroadcast these uplink wireless transmission to the exterior of the cabinet via the external antenna.

### CROSS-REFRENCE TO RELATED APPLICATION

The present application claims priority under 35 U.S.C. § 119 from U.S. Provisional Application Ser. No. 62/378,783, entitled “ELECTRONIC EQUIPMENT CABINETS HAVING RADIO FREQUENCY RELAYS,” filed on Aug. 24, 2016, the entire disclosure of which is hereby incorporated by reference herein for all purposes as if set forth in its entirety.

### TECHNICAL FIELD

The present disclosure relates generally to cabinets, and more specifically to cabinets for electronic equipment.

### BACKGROUND

Cabinets for electronic equipment have become popular in recent years, and are now routinely used in both indoor and outdoor applications. These cabinets, which are typically made of metal, are used to protect and provide convenient access to a wide variety of electronic equipment. For example, electronic equipment cabinets are used at cellular base stations to store radios, multicarrier power amplifiers, power supplies, batteries, backhaul equipment, baseband units and other equipment. Electronic equipment cabinets are also used in various other applications such as, for example, in data centers, computer rooms and microwave radio installations. These cabinets can protect the electronic equipment from environmental conditions and/or tampering, and may also provide RF shielding to the electronic equipment.

### SUMMARY

Aspects of the present disclosure provide an electronic equipment cabinet. The electronic equipment cabinet may include a cabinet having a plurality of walls including at least a rear wall, two side walls and a top wall, and a plurality of electronic devices. Each electronic device located within the cabinet and at least some of the electronic devices may include a respective wireless transceiver. The electronic equipment cabinet may include a relay comprising an internal antenna, an external antenna and a transmission path therebetween. The internal antenna may be located at least partially within the cabinet and the external antenna may be located at least partially exterior to a wall of the cabinet. The relay may be configured to receive uplink wireless transmissions from the wireless transceivers of the electronic devices and to forward and rebroadcast these uplink wireless transmission to the exterior of the cabinet via the external antenna.

Other aspects of the present disclosure provide a method. The method may include receiving at an internal antenna of a relay a radio frequency (“RF”) signal transmitted by an electronic device that is mounted within a metal cabinet. The internal antenna may be at least partially within the metal cabinet. The method may further include forwarding the received RF signal to an external antenna that transmits the received RF signal externally to the metal cabinet.

Other aspects of the present disclosure provide a relay. The relay may include an internal antenna, an external antenna, and a transmission path between the internal antenna and the external antenna. The internal antenna may be dimensioned to sit at least partially within an electronics cabinet and the external antenna is dimensioned to sit at least partially exterior to a wall of the electronics cabinet.

### BRIEF DESCRIPTION OF FIGURES

FIG. 1 is a schematic perspective view of an electronic equipment cabinet according to embodiments of the present invention.

FIG. 2 is a schematic view of a cellular base station at which the cabinets according to embodiments of the present invention may be used.

FIG. 3 is a schematic block diagram of a relay that may be included in the cabinets according to embodiments of the present invention.

FIGS. 4A-4C are schematic cross-sectional views illustrating three example ways that a relay according to embodiments of the present invention may be mounted in a wall of an electronic equipment cabinet.

FIGS. 5-10 are schematic views of relays for electronic equipment cabinets according to certain embodiments of the present invention.

### DETAILED DESCRIPTION

A current trend is for electronic devices to have increased sensing and communications connectivity, along with an increased ability to monitor their own status and communicate that status to remote devices. For example, the nascent Internet-of-Things (“IoT”) movement envisions providing a wide variety of electronic devices and other objects (e.g., clothing, accessories, etc.) with sensors, processing capabilities and low power wireless transceivers. This hardware allows these devices/objects to broadcast information such as status, location, health, environmental and/or other information to an external communications network such as, for example, a low power wide access IoT communications network such as the low power networks provided by Sigfox® or LoRa® or the recently standardized narrow-band Internet-of-Things (NB-IOT). As an example, an electronic device such as an appliance may have internal sensors that monitor the health of appliance's internal electronics and upon detecting a potential issue may transmit a few ultra-low power bytes of information to notify a user or other entity that a potential problem has been detected. The functionality of electronic devices that are installed in various electronic equipment cabinets may similarly be enhanced with access to a wireless data network, which may allow these devices to, for example, intermittently transmit status information, alarms and/or sensor data to remote locations. This may reduce maintenance requirements, outages due to equipment failure and/or equipment redundancy requirements as the electronic devices themselves may request maintenance or replacement prior to failure.

Electronic devices that are stored in cabinets at cellular base stations and other locations may similarly be configured to communicate with other devices using one or more wireless data transmission protocols, such as protocols which use radio frequencies in the industrial, scientific, and medical (ISM) radio bands. For example, amplifiers and cellular base station back-up batteries may include a Bluetooth or ZigBee transceiver, backhaul equipment may include an LTE transceiver, and power supplies may also include wired or wireless communications capabilities. Unfortunately, a metal cabinet acts like a Faraday cage that blocks the transmission of radio frequency (“RF”) signals. Thus, when IoT-equipped electronic devices such as, for example, radios, amplifiers, power supplies, batteries, backhaul equipment and the like are stored in metal electronic equipment cabinets, the IoT functionality may not be operable as the wireless IoT transceivers included in these devices may not be able to communicate through the metal cabinet with the wide access IoT communication network. It will be appreciated that the metal cabinets often are not completely sealed by metal as they typically have openings for cable egress or other functions. However, the amount of metal is typically sufficient that there may be significant impairment disrupting any RF communications link such that the IoT transceivers may not be able to reliably communicate through the metal cabinet.

Pursuant to embodiments of the present invention, electronic equipment cabinets are provided that include relays that allow IoT or other RF transceivers included on electronic equipment that is stored within the cabinet to communicate with networks that are external to the cabinet such as the above-mentioned wide access IoT communication network. These relays may extend through a wall of the cabinet and receive IoT signals transmitted therein and then pass these signals through the cabinet and re-radiate the signals to the external network. In some embodiments, the relays may operate entirely at RF. In some embodiments, the relays may be completely passive relays, while in other embodiments the relays may include active equipment such as, for example, low noise amplifiers that are used to increase the power level of the retransmitted RF signals. The relays may also be two-way devices that may be used not only to transmit signals from the devices in the cabinet to an external network, but also to transmit signals from the external network to devices within the cabinet.

The present invention will now be described in greater detail with reference to the attached figures in which example embodiments of the invention are illustrated.

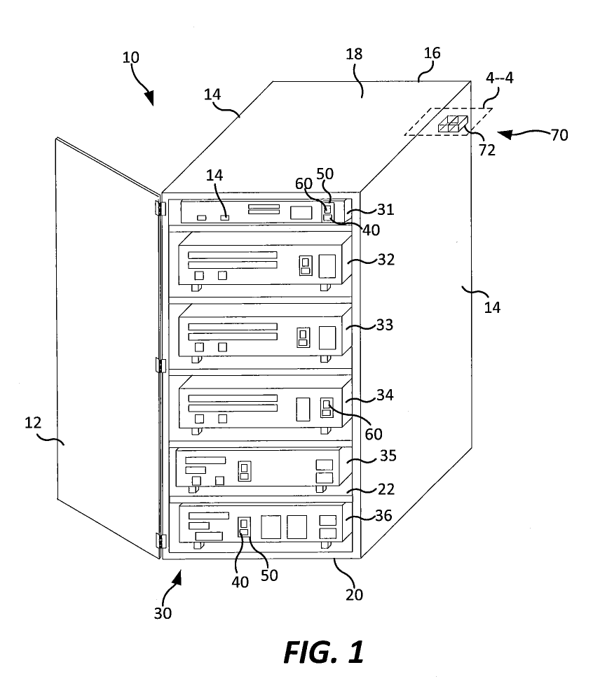

An electronic equipment cabinet, designated broadly at 10, is shown in FIG. 1. The cabinet 10 may be a generally box-shaped structure, with a front door 12, opposed sidewalls 14, a rear wall 16 (which may include removable panels that cover access windows), a top wall (ceiling) 18, and a bottom wall (floor) 20. The structural components of the cabinet 10 may be conventional in nature and need not be described in detail herein. In example embodiments, the front door 12 may be positioned between about 18 and 28 inches from the rear wall 16, and the cabinet 10 may be between about 60 and 84 inches in height.

A plurality of shelves 22 may be provided and various electronic devices 30 may be mounted on these shelves 22. While the electronic devices 30 are mounted on shelves 22 in the depicted embodiment, it will be appreciated that the electronic equipment 30 may alternatively be mounted within the cabinet 10 using vertical rack structures (not shown).

The electronic devices 30 depicted within the example cabinet 10 are a cabinet controller 31, a power supply 32, a multicarrier power amplifiers 33, a battery 34, a baseband unit 35 and backhaul equipment 36. The depicted electronic devices 30 are examples of representative types of electronic equipment that are often stored in metal cabinets at cellular base stations. Each of these depicted electronic devices 30 may provide conventional functionality, which is not described at length herein. The electronic devices 30 illustrated in FIG. 1 are drawn schematically and are for illustrative purposes only. The sizes and locations of the electronic devices 30 within the cabinet 10 are not necessarily to scale.

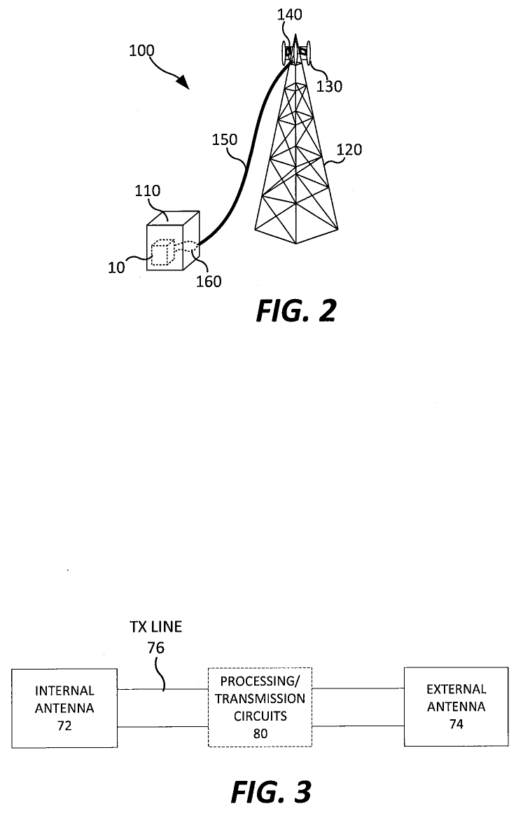

The electronic devices 30 may be connected to each other and/or to electronic devices that are external to the cabinet 10. For example, FIG. 2 is a schematic diagram illustrating a cellular base station 100 that includes an equipment enclosure 110 that has the cabinet of FIG. 1 installed therein. As shown in FIG. 2, the base station 100 further includes a tower 120, a plurality of antennas 130 mounted thereon, and a remote radio head 140 mounted behind each antenna 130. A trunk cable 150 may extend from the equipment enclosure 110 to the top of the tower 120. Jumper cables 160 such as, for example, power jumper cables and optical jumper cables may extend from the cabinet 10 to the trunk cable 150 within the equipment enclosure 110 and from the trunk cable 150 to the remote radio heads 140 at the top of the tower 120.

Referring again to FIG. 1, some or all of the electronic devices 30 may include wireless transceivers 40, IoT processors 50 and/or sensors 60. Each of the wireless transceivers 40, and by extension their associated electronic devices 30, may be individually addressable. The wireless transceivers 40 may include both transmit and receive functionality, or only have one of transmit or receive capabilities. It will be appreciated that the term “wireless transceiver” is used broadly herein to cover all three types of devices. The sensors 60 may include any of a wide variety of sensors that monitor internal conditions and operation of the electronic device 30 and/or that monitor external conditions such as, for example, environmental conditions. The processor 50 may control and/or receive information from the sensors 60, may process the received information (e.g., to make predictions) and may control the wireless transceiver 40 to transmit messages to an external communications network. The processor 50 may also receive messages (via the wireless transceiver 40) from the external communications network and control operation of the electronic device 30 in response thereto.

The wireless transceivers 40 may be, for example, low power wireless transceivers that are configured to communicate using Bluetooth, Wi-Fi, Zigbee, Z Wave, Sigfox®, LoRa®, RPMA, Weightless, NB-IoT, cellular Low Power Wide Access (LPWA), or other networks or communication protocols. In other embodiments, the wireless transceivers 40 may transmit and/or receive signals using radio waves in the industrial, scientific, and medical (ISM) radio bands, e.g., radio bands reserved for purposes other than telecommunications. In some embodiments, the communications may be in licensed radio bands while in other embodiments unlicensed radio bands may be used. In some embodiments, the wireless transceivers 40 may be configured to communicate according to a standardized Internet-of-Things communications protocol such as, for example, the protocols for the Sigfox® or LoRa® IoT communications networks or the recently standardized NB-IOTcommunications protocol that may communicate via either Global System for Mobile Communications (“GSM”) or Long-Term Evolution (“LTE”) cellular radio systems. It will be appreciated that the wireless transceivers 40 may also be configured to communicate with other wide area networks such as WiFi networks (e.g., 802.11 networks), Worldwide Interoperability for Microwave Access (WiMAX), Universal Mobile Telecommunications System (UMTS), CDMA2000, Evolution-Data Optimized (EV-DO), Ultra Mobile Broadband (UMB), any other 2nd, 3rd, 4th and higher generation cellular communications networks and various other wide band wireless networks.

The sensors 60 may provide device and/or environmental data to the processor 50. The device data may comprise, for example, various measured voltage, current and/or temperature levels at nodes within the electronic device and/or components thereof. The processor 50 may, for example, process the received voltage, current and/or temperature levels and identify faults or error conditions and/or make predictions regarding future failures. For example, a power amplifier, capacitor or the like within an electronic device 30 that is starting to fail may exhibit increased and/or decreased voltage, current or temperature levels that alone or in combination indicate a failure or an increased probability of a failure. The sensors 60 may detect such changes and pass this information to the processor 50 which processes the information and predicts a possible current or future fault condition based thereon. The processor 50 may generate a message and cause this message to be transmitted by the wireless transceiver 40 over an external communications network to notify an external entity of the possible current or future fault condition.

While fault prediction and detection is one type of functionality that may be provided in electronic devices 30 that include IoT transceivers 40, it will be appreciated that the electronic devices 30 may collect and transmit a wide variety of other information. For example, IoT enabled devices may include external environmental sensors such as thermometers, barometers, moisture detectors and the like that collect environmental data and/or sense motion. Numerous other environmental sensors are possible. As another example, the electronic devices 30 may include motion detectors and/or accelerometers that may be used to detect movement of the electronic devices 30 or motion in the vicinity thereof.

The processor 50 and/or the sensors 60 associated with a given electronic device 30 may be used to monitor various aspects of the electronic device 30 and may generate status information such as location information, health information, environmental information and the like. For example, the processor 50 and sensors 60 associated with a particular electronic device 30 may detect failure of components of the electronic device 30, may predict when future failure of components is likely, may detect when the electronic device 30 is not operating within specifications and the like. When component failures or out-of-specification operation is detected or predicted, the processor 50 may forward messages to the wireless transceiver 40 associated with the electronic device 30 for communication to an external communications network. The processor 50 may likewise intermittently transmit status information or environmental information collected by the sensors 60 to the external communications network.

As noted above, the construction of the cabinet 10 may prevent wireless signals emanating from sources outside the cabinet 10 from entering the cabinet 10, and/or may prevent wireless signals emitted from electronic devices 30 inside the cabinet 10 from exiting the cabinet 10. For example, the wireless transceivers 40 on the electronic devices 30 may intermittently transmit status and/or alarm signals that are to be transmitted to an intended recipient over a wireless communications network such as, for example, a NB-IoT network operating over an LTE cellular network. Because the metal walls of the cabinet 10 provide RF shielding, the NB-IoT signals transmitted by the wireless transceivers 40 may not exit the cabinet 10 with sufficient power to be received by the NB-IoT network.

To address this problem, the electronics cabinet 10 according to embodiments of the present invention also includes a relay 70. The relay 70 may be manufactured integral with the cabinet 10 or may be a separate unit that is mounted on or in the cabinet 10. The relay 70 may be located at any suitable location within the cabinet 10. Typically, a first part of the relay 70 will be within the cabinet 10 and a second portion of the relay may be located outside the cabinet 10. The relay 70 may be used to relay signals transmitted by the wireless transceivers 40 outside the cabinet 10 and may be used to relay signals transmitted by an external communications network into the interior of the cabinet 10 where such signals may be received by the wireless transceivers 40.

As will be discussed in greater detail below, the relay 70 may comprise a passive or active device that is configured to forward transmissions from within the cabinet 10 to the exterior of the cabinet 10 and to forward signals incident on the exterior of the cabinet 10 into the interior of the cabinet 10. When implemented as a passive device, the relay 70 may be as simple as a first antenna that is on the exterior of the cabinet 10, a second antenna that is on the interior of the cabinet 10 and a transmission line connecting these two antennas. When implemented as an active device, the relay 70 may include, for example, one or more amplifiers such as a low-noise amplifier that amplify signals received at the first antenna before they are passed to the second antenna (and vice versa). The relay 70 may also, in some embodiments, convert between communications protocols and/or have other functionality. The relay 70 may forward messages, instructions, commands, requests, status updates, status predictions, data, or other information both to and from the electronic devices 30 to remote locations.

FIG. 3 is a schematic block diagram that illustrates the basic components of an example relay according to some embodiments of the present invention. As shown in FIG. 3, the relay includes an internal antenna 72, an external antenna 74 and a transmission path 76. The antennas 72 and 74 may be omnidirectional or quasi omnidirectional antennas in some embodiments. The use of such omnidirectional antennas may allow the wireless transceivers 40 on the electronic devices 30 to be located at any orientation within the cabinet 10 with respect to the antenna 72, which may provide maximum flexibility regarding the locations for the electronic devices 30, the wireless transceivers 40 mounted thereon and the relay 70. In some embodiments, either or both the antennas 72, 74 may comprise monopole antennas. If the communications with the wireless transceivers 40 are two-way communications and the communications occur in separate transmit and receive frequency bands, then, in some embodiments, the antennas 72, 74 may comprise “wideband” antennas that may be used to transmit and receive signals in both the transmit and receive frequency bands. As will be discussed herein, in other embodiments, the relay 70 may include two internal antennas 72 that are used to transmit and receive signals in the separate transmit and receive frequency bands and two external antennas 74 that are likewise used to transmit and receive signals in the separate transmit and receive frequency bands. In such embodiments, a transmission line 76 may be provided between each pair of internal and external antennas 72, 74. The relay 70 may also include various processing and transmission functionality 80 which may be located along the transmission path 76 between the internal antenna 72 and the external antenna 74.

In some embodiments, the relay may be an RF relay that receives RF signals at a first antenna 72, 74 thereof and relays these received RF signals to the other of the antennas 72, 74 for retransmission at RF. In such embodiments, the signals are always maintained at RF without conversion to an intermediate frequency or baseband. The use of such RF relays may greatly simplify the design of the relay 70. When such RF relays are used, the transmission path 76 may be any appropriate RF transmission path such as, for example, a coaxial cable, an RF stripline, a microstrip transmission line or the like. In other embodiments, the relay 70 may include additional functionality such as, for example, the ability to convert between different communications protocols, separate intelligence such as, for example, its own sensors and processing capabilities and/or the ability to read and process communications from the wireless transceivers 40 which may allow the relay 70 to make predictions based on the information from a plurality of electronic devices to more quickly and accurately identify when problems are occurring within the cabinet 10.

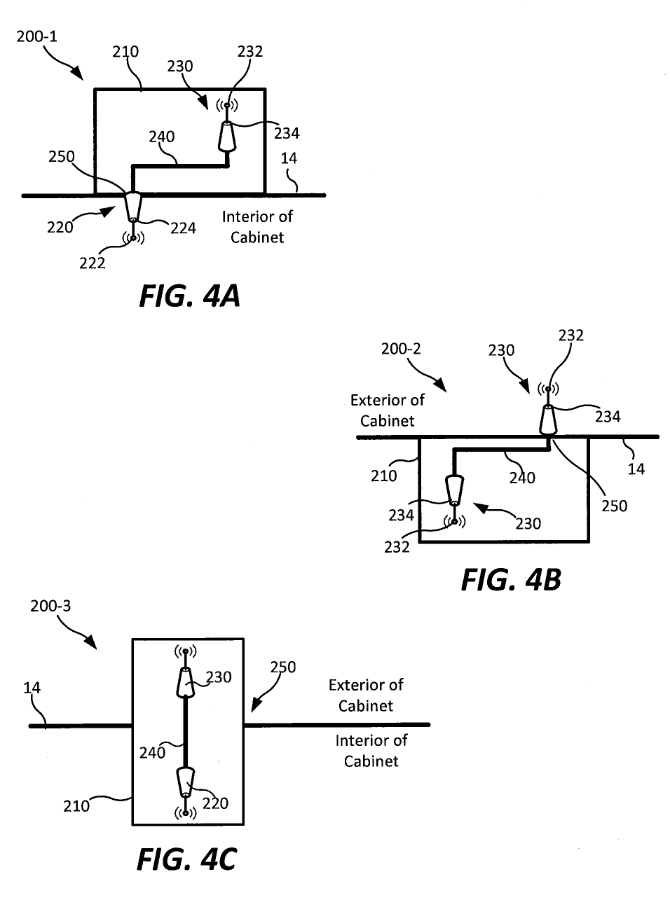

FIGS. 4A-4C are schematic horizontal cross-sectional views of the portion of FIG. 1 within the dashed box labelled 4-4. FIGS. 4A-4C schematically illustrate several exemplary ways that relays according to embodiments of the present invention may be mounted within an electronic equipment cabinet such as the cabinet 10 of FIG. 1.

Referring first to FIG. 4A, a relay 200-1 is illustrated that is primarily mounted external to the cabinet 10. As shown in FIG. 4A, the relay 200-1 includes a housing 210 that extends outwardly from the sidewall 14 of cabinet 10. The housing 210 may comprise, for example, a rigid material that readily passes RF signals such as various plastics (e.g., plastic materials that are used to form radomes). The housing 210 may be affixed to the sidewall 14 of the cabinet 10 via screws, tape, glue, epoxy and the like. An external antenna 230 is mounted within the housing 210 such that the external antenna 230 at least extends partly beyond the sidewall 14 to the exterior of the cabinet 10. The external antenna 230 may comprise for example, a monopole antenna 230 that includes a monopole radiating element 232 that is mounted above a ground plane 234. The external antenna 230 may receive signals from an external communications network and may also be used to transmit signals that are received from within the cabinet 10 to the external network.

The relay 200-1 further includes an internal antenna 220 that is mounted at least partly within the interior of the cabinet 10. The internal antenna 220 may also comprise, for example, a monopole antenna 220 that includes a monopole radiating element 222 that is mounted above a ground plane 224. The relay 200-1 further includes a transmission path 240 that connects the external antenna 230 to the internal antenna 220. The transmission path 240 may comprise any suitable transmission path for RF signals. The sidewall 14 includes an opening 250. The transmission path 240 may extend though the opening 250 in some embodiments, while the internal antenna 220 may extend through the opening 250 in other embodiments.

Referring next to FIG. 4B, a relay 200-2 is illustrated that is primarily mounted internal to the cabinet 10. As shown in FIG. 4B, the relay 200-2 may be identical to relay 200-1 except that the housing 210 and other components of relay 200-2 are primarily located within the interior of the cabinet 10, except that at least a portion of the external antenna 230 protrudes through an opening 250 in sidewall 14 external to the cabinet 10. In light of the similarities to relay 200-1, further description of relay 200-2 will be omitted.

FIG. 4C illustrates another relay 200-3 according to embodiments of the present invention that is mounted through an opening 250 in a sidewall 14 of the cabinet 10. As shown in FIG. 4C, the relay 200-3 includes a housing 210′ that extends through the opening 250. For example, the opening 250 may comprise a rectangular slot in the sidewall 14 and the relay housing 210 may be a rectangular box that fits through this slot 250. As shown in FIG. 4C, the internal antenna 220 may be mounted within the housing 210 to extend into the interior of the cabinet 10 and the external antenna 230 may be mounted within the housing 210 to be external to the cabinet. A transmission path 240 may connect the antennas 220, 230.

While FIGS. 4A-4C illustrate the relay mounted on or through a sidewall 14 of the cabinet, it will be appreciated that relays disclosed therein could be mounted on or through the ceiling 18, floor 20, rear wall 16 or front door/wall 12 in other embodiments.

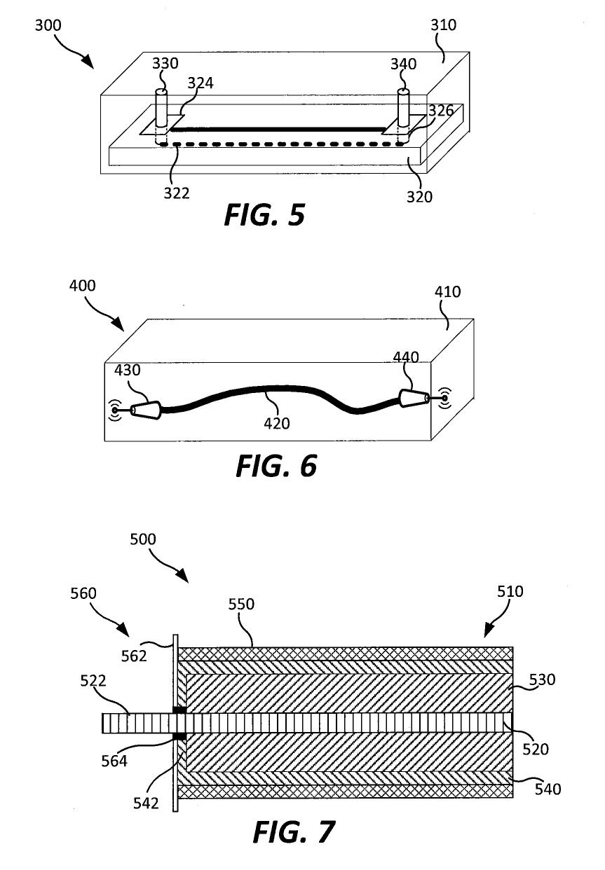

FIG. 5 is a schematic perspective view of a relay for an electronic equipment cabinet according to embodiments of the present invention. As shown in FIG. 5, the relay 300 includes a housing 310 that has a board 320 mounted therein. The housing 310 may include slots or tabs or other mounting structures (not shown) on internal walls thereof that are used to mount the board 320. The board 320 may comprise, for example, a microstrip or stripline structure that includes an RF transmission line 322 formed therein or thereon. In the depicted embodiment, a portion of the RF transmission line 322 is formed on the lower side of the board 320 and hence is depicted using a dashed line. The board 320 may further include a pair of metallic pads 324 near either end thereof. An opening 326 may be provided through each pad 324 and may extend through the board. An internal monopole antenna 330 is mounted in a first of the openings 326 and an external monopole antenna 340 is mounted in the second of the openings 326. Each monopole antenna 330, 340 may be connected to the microstrip or stripline transmission line 322. The pads 324 may serve as reflective ground planes for the monopole antennas 330, 340, and may be electrically connected to a ground conductor of the transmission line 322. The relay 300 may have a very small footprint, with the board having a length of a few inches or less in some embodiments. A slot may be cut through a wall of the cabinet 10, and the relay 300 may be mounted in this slot.

FIG. 6 is a schematic perspective view of a relay 400 for an electronic equipment cabinet according to further embodiments of the present invention. As shown in FIG. 6, the relay 400 includes a housing 410, a coaxial cable 420, an internal antenna 430 that is connected to one end of the coaxial cable 420 and an external antenna 440 that is connected to the other end of the coaxial cable 420. The antennas 430, 440 may comprise, for example, monopole antennas. The relay 400 may be mounted to extend through an opening in a wall of an electronic equipment cabinet.

FIG. 7 is a schematic side view of a portion of a relay 500 according to still further embodiments of the present invention. In FIG. 7, only the internal antenna 560 and a portion of the transmission line 510 are illustrated to simplify the drawing. It will be appreciated that an external antenna may be formed on the opposite end of the transmission line 510 and may be identical to the internal antenna 560.

As shown in FIG. 7, the relay 500 includes a transmission line 510 in the form of a coaxial cable. The coaxial cable 510 includes a center conductor 520, a dielectric spacer 530 that circumferentially surrounds the center conductor 520, an outer conductor 540 that circumferentially surrounds the dielectric spacer 530, and a tubular cable jacket 550 that covers the outer surface of the outer conductor 540. The dielectric spacer 530 and the outer conductor 540 may each have an annular cross-section. The internal antenna 560 is formed using a first end portion of the center conductor 520 and a conductive ground plane 562. The portion 522 of the center conductor 520 that extends beyond the conductive ground plane 562 may be, for example, about one-quarter a wavelength in length, where the wavelength is the center frequency of the frequency band at which the antenna 560 transmits and receives signals. The conductive ground plane 562 may comprise a thin sheet of metal that is electrically connected to the outer conductor 540. As shown, the coaxial cable 510 may be cut so that the outer conductor 540 has an extension 542 that extends beyond the dielectric spacer 530. This extension 542 may be bent toward the center of the coaxial cable 510. This may help provide a better electrical contact between the outer conductor 540 and the ground plane 562. An insulating spacer 564 may surround the center conductor 520 to isolate the outer conductor 540 and the ground plane 562 from the center conductor 520. The internal antenna 560 may comprise an omnidirectional monopole antenna that may be very simply formed. While not shown in FIG. 7, the relay 500 may have a housing in which the coaxial cable 510, the internal antenna 560 and the external antenna are mounted in some embodiments.

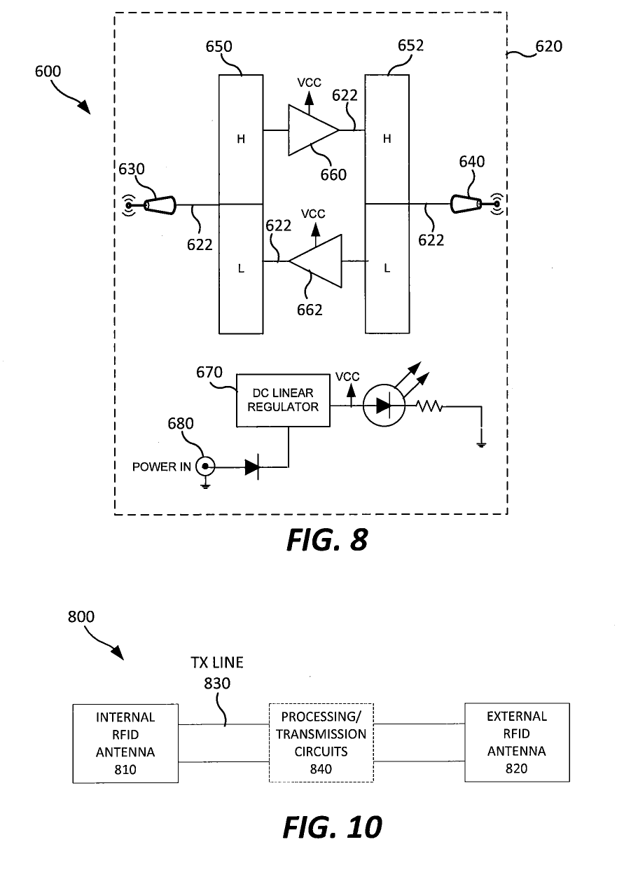

The relays 300, 400, 500 of FIGS. 5-7 are passive relays. As noted above, in other embodiments the relay may comprise an active device that includes, for example, an amplifier. FIG. 8 is a schematic circuit diagram of one such active relay 600. The active relay 600 may be implemented, for example, on a board in the same manner as the relay 300 of FIG. 5 described above, except that the relay may include additional components on the board such as, for example, a pair of diplexers, a pair of amplifiers and a DC voltage regulator to provide DC power to the amplifiers. Thus, the description of the relay 600 will focus on the differences between the relay 600 and the relay 300.

As shown in FIG. 8, the relay 600 includes a board such as a circuit board 620 that may be mounted in a housing (not shown). The circuit board 620 may comprise, for example, a microstrip or stripline structure that includes RF transmission line segments 622 formed therein or thereon. An internal monopole antenna 630 is mounted proximate a first end of the circuit board 620 and an external monopole antenna 640 is mounted proximate a second end of the circuit board 620. Each monopole antenna 630, 640 may be connected to one of the microstrip or stripline transmission line segments 622. The circuit board 620 may further include surface mount components in the form of a pair of diplexers 650, 652 and a pair of amplifiers 660, 662. The diplexers 650, 652 may filter signals received at the respective antennas 630, 640 into respective uplink and downlink portions, where the uplink signals refer to the signals transmitted from the electronic devices 30 within the cabinet 10 to an external communications network, and the downlink signals refer to the signals transmitted from the external communications network to the electronic devices 30 within the cabinet 10. Uplink signals received by the internal antenna 630 may be routed by the diplexer 650 to the uplink amplifier 660 and these signals are then passed by the diplexer 652 to the external antenna 640 for retransmission external to the cabinet 10. Downlink signals received by the external antenna 640 may be routed by the diplexer 652 to the downlink amplifier 662 and these signals are then passed by the diplexer 650 to the internal antenna 630 for retransmission within the cabinet 10. A DC linear regulator 670 may receive power from an external source 680 and provide an operating voltage VCC to the amplifiers 660, 662.

While in the above-describe d embodiments the external antenna is located in the immediate vicinity of the cabinet, it will be appreciated that this need not be the case. Cabinets are now routinely being located underground as Metrocell and other cellular base stations are deployed where the base stations antennas are mounted on streetlights, utility poles and other locations in urban areas to serve small, densely populated areas. When cabinets are located underground in the above-described or other applications, communications from the IoT transceivers 40 to the external communications network may be blocked by both the metal cabinet and the underground cabinet placement.

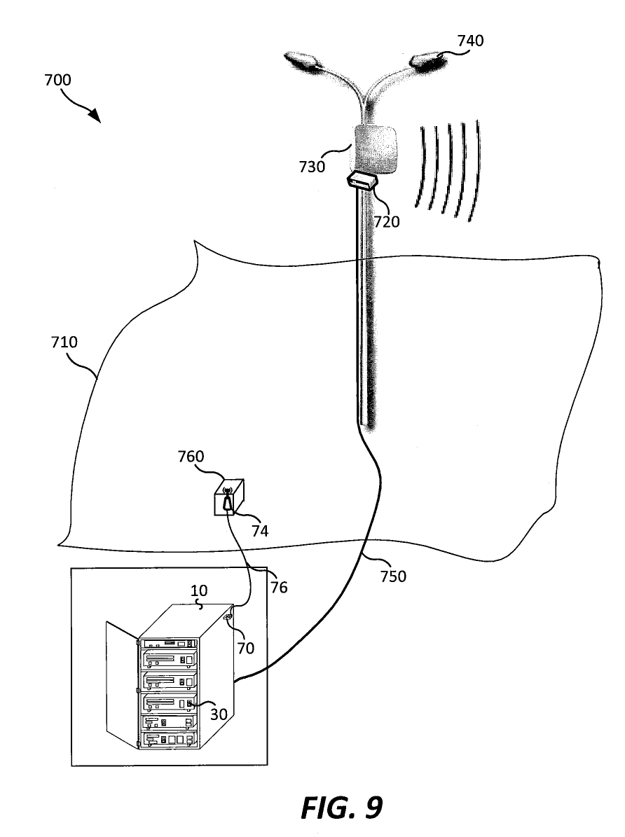

FIG. 9 is a schematic diagram illustrating an installation 700 in which an electronic equipment cabinet 10 according to embodiments of the present invention is installed in an underground location. As shown in FIG. 9, a metal cabinet 10 is located below the surface 710 of the earth. Electronic equipment 30 is mounted in the cabinet 10 and connected to a remote radio head 720 and an antenna 730 that are mounted on a streetlight 740 via a trunk cable 750. The cabinet 10 includes a relay 70 which may be, for example, any of the relays disclosed herein. As described above with respect to FIG. 3, the relay 70 may have an internal antenna 72 (not shown in FIG. 9) and an external antenna 74 that are connected by a transmission path 76. The transmission path 76 may be extended so that the external antenna 74 may be located above ground in, for example, an enclosure 760 (which may be located at any convenient location). The transmission path 76 may comprise a single transmission line such as a coaxial cable or may comprise a plurality of transmission lines (e.g., a printed circuit board transmission line and a coaxial cable that is attached thereto). By locating the external antenna 74 above ground, reliable communications between the IoT transceivers 40 on the electronic devices 30 and the external communications network may be maintained.

The relays described above with reference to FIGS. 5-8 are relatively simple, low cost implementations that maintain the signals at RE. As noted above in the discussion of FIG. 3, in other embodiments more sophisticated relays may be provided that, for example, down-convert signals received from the electronic devices 30 and/or from the external communications network to an intermediate frequency or baseband and then up-convert the signals to RF where they are retransmitted. In such embodiments, the relay may, for example, convert from one communication protocol to another (e.g., from Zigbee to NB-IoT). It will also be appreciated that the relays according to embodiments of the present invention may include their own sensors and/or processing capabilities. In such embodiments, the relays may monitor communications from the electronic devices 30 and may transmit messages based on conclusions drawn from the aggregated communications.

Most of the relays described above include a single internal antenna and a single external antenna. It will be appreciated that in other embodiments more than one internal and/or external antenna may be provided. For example, in some embodiments two internal antennas and two external antennas may be provided for purposes of diversity. In such embodiments, a second transmission line may be provided to connect the second internal antenna to the second external antenna. In still further embodiments, the internal antenna may be replaced with a distributed antenna system that has a plurality of radiating elements distributed throughout the interior of the cabinet 10. In still other embodiments, a distributed external antenna may be provided (e.g., with external radiating elements located on multiple walls of the cabinet 10). It will be appreciated that any of the above embodiments may be combined and that numerous other embodiments are possible.

The relays according to embodiments of the present disclosure may operate as follows. Referring to FIG. 1, an electronic device 30 within a cabinet 10 may, for example, collect information from an internal or external sensor 60. The processor 50 on the electronic device 30 may form a message in response thereto and pass the message to the wireless transceiver 40 for transmission. A signal containing the message is transmitted by the transceiver 40, but will typically not escape the cabinet 10 due to the metal walls.

Referring to FIG. 3, the internal antenna 72 on the relay 70 is disposed within the interior of the cabinet 10 and hence may receive the signal transmitted by the wireless transceiver 40. The received signal is carried over the transmission line 76 to the external antenna 74 which reradiates the signal external to the cabinet 10. This reradiated signal may then be received by an external communications network. As noted above, the signal received by the internal antenna 72 may be amplified and/or further processed in some embodiments. Signals from the external communications network may be forwarded by the relay 70 in the same manner (but in the reverse direction) to the wireless transceiver 40 on the electronic device 30.

Pursuant to further embodiments of the present invention, electronic equipment cabinets are provided that include internal radio frequency identification (“RFID”) antennas mounted within the interior of the cabinet and relays that transmit signals received by the RFID antennas to an external communications network. RFID is now used in a number of applications to track electronic equipment. However, RFID signals may be blocked by metal cabinets in the same manner that IoT wireless transmissions may be blocked as described above. FIG. 10 is a schematic block diagram of an RFID relay 800 according to embodiments of the present invention that may be mounted in or on a metal electronic equipment cabinet (not shown). As shown in FIG. 10, the relay includes an internal antenna 810, an external antenna 820 and a transmission path 830. The antennas 810, 820 may be conventional RFID antennas in some embodiments. The transmission line 830 connects the internal and external antennas 810, 820. The relay 800 may also include various processing and transmission functionality 840 which may be located along the transmission path 830 between the internal antenna 810 and the external antenna 820.

In some embodiments, the relay 800 may be an RF relay that receives RFID excitation signals at the external antenna 820 and relays these excitation signals to the internal antenna 810 via the transmission line 830. The internal antenna 810 broadcasts the RFID excitation signal within the metal cabinet that the relay 800 is installed in or on. Electronic devices within the cabinet may have RFID tags mounted thereon. As known in the art, RFID tags include an RFID antenna and an integrated circuit that includes a memory. The RFID excitation signal is used to power the RFID tags and in response to the RFID excitation signal each RFID tag may transmit a responsive signal that includes data stored in the memory thereof. RFID tags may be designed to follow arbitration procedures that ensure that when multiple RFID tags are excited by an RFID excitation signal the RFID tags respond serially to avoid interfering with each other. The internal antenna 810 receives the responsive RFID signals from the RFID tags and this signal is carried over the transmission line 830 to the external antenna 820 that rebroadcasts these signals so that they may be received by an RFID reader that transmitted the RFID excitation signal.

While in the above description the relay 800 maintains the RFID signals at their original RF frequencies, it will be appreciated that in other embodiments the RFID signals may be converted to an intermediate frequency (“IF”) or baseband in the same manner, discussed above, that IoT transmissions can be converted to IF or baseband. It will likewise be appreciated that the relay 800 may include one or more amplifiers that may amplify either or both the RFID excitation signal and/or the responsive RFID signals. Finally, it will also be appreciated that the RFID relay 800 may be added to any of the IoT relays according to embodiments of the present invention.

Embodiments of the present invention have been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, operations, elements, and/or components, but do not preclude the presence or addition of one or more other features, operations, elements, components, and/or groups thereof.

Aspects and elements of all of the embodiments disclosed above can be combined in any way and/or combination with aspects or elements of other embodiments to provide a plurality of additional embodiments.

That which is claimed is:

1. An electronic equipment cabinet, comprising:
a cabinet having a plurality of walls including at least a rear wall, two side walls and a top wall;
a plurality of electronic devices, each electronic device located within the cabinet and at least some of the electronic devices including a respective wireless transceiver; and
a relay comprising an internal antenna, an external antenna and a transmission path therebetween, wherein the internal antenna is located at least partially within the cabinet and the external antenna is located at least partially exterior to a wall of the cabinet, and wherein the relay is configured to receive uplink wireless transmissions from the wireless transceivers of the electronic devices and to forward and rebroadcast these uplink wireless transmission to the exterior of the cabinet via the external antenna.

2. The electronic equipment cabinet of claim 1, wherein the relay is further configured to receive, via the external antenna, a downlink wireless transmission destined for a first of the electronic devices and to forward and rebroadcast the downlink wireless transmission to the first electronic device via the internal antenna.

3. The electronic equipment cabinet of claim 1, wherein the relay comprises a board with an RF transmission line thereon.

4. The electronic equipment cabinet of claim 3, wherein at least one of the internal antenna and the external antenna is mounted on the board.

5. The electronic equipment cabinet of claim 4, wherein the internal antenna comprises a monopole antenna and the external antenna comprises a monopole antenna.

6. The electronic equipment cabinet of claim 1, wherein the relay further comprises an amplifier that amplifies signals received by the internal antenna.

7. The electronic equipment cabinet of claim 1, wherein the transmission path comprises a coaxial cable.

8. The electronic equipment cabinet of claim 7, wherein a first end of the center conductor of the coaxial cable comprises part of the internal antenna, and a second end of the center conductor of the coaxial cable comprises part of the external antenna.

9. The electronic equipment cabinet of claim 7, wherein the transmission path comprises an RF transmission line that directly connects the internal and external antennas.

10. The electronic equipment cabinet of claim 7, wherein the relay includes at least one sensor.

11. The electronic equipment cabinet of claim 1, wherein the external antenna is located remotely from the cabinet.

12. The electronic equipment cabinet of claim 11, wherein the cabinet is located underground and the external antenna is above ground.

13. The electronic equipment cabinet of claim 1, further comprising an internal RFID antenna, an external RFID antenna, and an RFID transmission line connecting the internal RFID antenna to the external RFID antenna.

14. A method comprising:
receiving at an internal antenna of a relay a radio frequency (“RF”) signal transmitted by an electronic device that is mounted within a metal cabinet, wherein the internal antenna is at least partially within the metal cabinet; and
forwarding the received RF signal to an external antenna that transmits the received RF signal externally to the metal cabinet.

15. The method of claim 14, wherein the RF signal is within a first frequency band, and wherein the forwarding comprises transmitting the RF signal without converting the RF signal to a different frequency band.

16. The method of claim 14, further comprising amplifying the received RF signal prior to transmitting the received RF signal externally to the metal cabinet.

17. A relay comprising:
an internal antenna,
an external antenna,
a transmission path between the internal antenna and the external antenna, wherein the internal antenna is dimensioned to sit at least partially within an electronics cabinet and the external antenna is dimensioned to sit at least partially exterior to a wall of the electronics cabinet.

18. The relay of claim 17, wherein the transmission path comprises a coaxial cable.

19. The relay of claim 17, further comprising:
a pair of diplexers,
a pair of amplifiers; and
a voltage regulator.

20. The relay of claim 17, wherein at least one of the internal antenna and the external antenna comprises an RFID antenna.
